(19) United States
(12) Patent Application Publication
(10) Pub. No.: US 2026/0169081 A1
(43) Pub. Date: Jun. 18, 2026

(54) METHOD FOR ESTIMATING A STATE OF CHARGE

(71) Applicants: MEAN WELL (GuangZhou) Electronics Co., Ltd., Guangzhou (CN); MEAN WELL Enterprises Co., Ltd., New Taipei City (TW)

(72) Inventors: Jyun-Jie Huang, New Taipei City (TW); Sheng-Kai Chung, New Taipei City (TW); Min-Qiang Hu, Guangzhou (CN)

(73) Assignees: MEAN WELL (GuangZhou) Electronics Co., Ltd., Guangzhou (CN); MEAN WELL Enterprises Co., Ltd., New Taipei City (TW)

(21) Appl. No.: 19/035,425

(22) Filed: Jan. 23, 2025

(30) Foreign Application Priority Data
Dec. 13, 2024 (CN) 202411844360.X

(51) Int. Cl. G01R 31/3835

(52) U.S. Cl. CPC G01R 31/3835

(57) ABSTRACT

In a method for estimating a state of charge, the state of charge of a battery in a charging process is calculated based on the Coulomb integration method until the battery enters a float charging mode. A first curve and a second curve are generated based on the state of charge, a corresponding charging voltage, and a corresponding charging current. After resting the battery, a first present resting open-circuit voltage of the battery is measured. A findable charging voltage and a findable charging current corresponding to the present state of charge of the battery are respectively found from the first curve and the second curve. Finally, a first resting state of charge of the battery is determined based on the present state of charge, the first present resting open-circuit voltage, the findable charging voltage, and the findable charging current.

### BACKGROUND OF THE INVENTION

This application claims priority for the CN patent application no. 202411844360X filed on 13 Dec. 2024, the content of which is incorporated by reference in its entirely.

### FIELD OF THE INVENTION

The present invention relates to an estimation method, particularly to a method for estimating a state of charge.

### DESCRIPTION OF THE RELATED ART

Batteries (including non-rechargeable batteries and rechargeable batteries) have a wide range of applications. For example, batteries can be used in electronic devices such as mobile phones, notebook computers, and portable medical equipment. Batteries can also be used in vehicles, such as gasoline vehicles, diesel vehicles, hybrid vehicles, electric-gas hybrid vehicles, or electric vehicles.

For some battery applications, it is important to provide accurate battery power to users or technicians. The battery's power represents power remaining in the battery (i.e., remaining battery power), power having been lost (i.e., aging battery power), or power having been discharged and consumed (i.e., discharged battery power). Therefore, the term “power” has three interpretations: discharged battery power, aging battery power, and remaining battery power. It is understood that the remaining battery power can be calculated based on the discharged battery power, and vice versa. For example, the remaining battery power can be obtained by subtracting the discharged battery power from the maximum battery power. Alternatively, the discharged battery power can be obtained by subtracting the remaining battery power from the maximum battery power. The technology for estimating battery power in the market today is commonly implemented with the Coulomb integration method or the open-circuit voltage look-up table method. The Coulomb integration method integrates the charge and discharge current of the battery in a period of time to estimate the battery's state of charge. The open-circuit voltage look-up table method estimates the state of charge (SOC) based on the battery's open-circuit voltage when the battery is in a resting state. However, the two methods have their own problems. When using the Coulomb integration method, the inaccurate remaining power is easily calculated based on accumulated errors caused by long-term calculations. Besides, the Coulomb integration method estimates the inaccurate power loss after battery aging. The open-circuit voltage look-up table method must build a table in advance and requires the battery to rest for a long enough time. That is to say, the open-circuit voltage look-up table method can achieve higher accuracy only when the battery is in a stable state.

To overcome the abovementioned problems, the present invention provides a method for estimating a state of charge, so as to solve the afore-mentioned problems of the prior art.

### SUMMARY OF THE INVENTION

The present invention provides a method for estimating a state of charge, which avoids the loss of battery capacity and errors in state of charge due to battery aging and uses a first curve of a charging voltage and a second curve of a charging current to implement the open-circuit voltage look-up table method without resting the battery for a long time.

In an embodiment of the present invention, a method for estimating a state of charge includes:
charging a battery and collecting a charging voltage and a charging current for charging the battery in a charging process;
resetting the initial state of charge of the battery to zero, calculating a remaining state of charge of the battery in the charging process based on the Coulomb integration method, the given battery capacity of the battery, and the charging current until the battery enters a float charging mode, generating a first curve of the charging voltage versus the remaining state of charge and a second curve of the charging current versus the remaining state of charge based on the remaining state of charge and the charging voltage and the charging current corresponding thereto, and calculating a present state of charge of the battery with the Coulomb integration method;
measuring a first present resting open-circuit voltage of the battery after resting the battery;
finding from the first curve a findable charging voltage corresponding to the present state of charge, finding from the second curve a findable charging current corresponding to the present state of charge, and recording a voltage difference between the findable charging voltage and the first present resting open-circuit voltage and the findable charging current;
calculating a first charging voltage based on the present state of charge, the first present resting open-circuit voltage, the voltage difference, and the findable charging current and finding from the first curve a first findable state of charge corresponding to the first charging voltage; and
determining whether the first findable state of charge is less than the present state of charge to determine a first resting state of charge of the battery:
   when the first findable state of charge is less than the present state of charge, subtracting a constant state of charge from the present state of charge to generate and output the first resting state of charge, wherein the constant state of charge is greater than 0% and the constant state of charge is less than or equal to 1%; and
   when the first findable state of charge is not less than the present state of charge, outputting the present state of charge as the first resting state of charge.

In an embodiment of the present invention, the method for estimating a state of charge further includes an update step. In the update step, a new battery capacity of the battery is calculated based on a start time point of the charging process, a time point corresponding to the float charging mode, and the charging current and the given battery capacity is replaced by the new battery capacity.

In an embodiment of the present invention, the method for estimating a state of charge further includes following steps before the step of charging the battery:
determining whether a voltage of the battery is in a warning voltage interval:
   when the voltage of the battery is in the warning voltage interval, charging the battery; and
   when the voltage of the battery is not in the warning voltage interval, ending.

In an embodiment of the present invention, before the battery enters the float charging mode, the remaining state of charge of the battery in the charging process is calculated based on the Coulomb integration method, the given battery capacity of the battery, and the charging current in a constant current mode and a constant voltage mode.

In an embodiment of the present invention, the constant current mode includes:
calculating the remaining state of charge of the battery in the charging process based on the Coulomb integration method, the given battery capacity of the battery, and the charging current and recording the cumulative number of times that the charging current is less than a given constant current; and
determining whether the cumulative number of times reaches a given value:
   when the cumulative number of times reaches the given value, ending; and
   when the cumulative number of times does not reach the given value, returning to the step of calculating the remaining state of charge of the battery in the charging process based on the Coulomb integration method, the given battery capacity of the battery, and the charging current and recording the cumulative number of times.

In an embodiment of the present invention, in the step of resting the battery, the battery is rested for a first given time period.

In an embodiment of the present invention, the method for estimating a state of charge further includes following steps after determining the first resting state of charge:
determining whether the battery is rested again for a second given time period:
   when the battery is not rested again for the second given time period, ending; and
   when the battery is rested again for the second given time period, performing following steps:
      measuring a second present resting open-circuit voltage of the battery, calculating a second charging voltage based on the latest resting state of charge, the latest second present resting open-circuit voltage, the voltage difference, and the findable charging current, and finding a second findable state of charge corresponding to the latest second charging voltage from the first curve; and
      determining whether the latest second findable state of charge is less than the latest resting state of charge to determine a second resting state of charge of the battery:
         when the latest second findable state of charge is less than the latest resting state of charge, subtracting the constant state of charge from the latest resting state of charge to generate and output the second resting state of charge; and
         when the latest second findable state of charge is not less than the latest resting state of charge, outputting the latest resting state of charge as the second resting state of charge.

In an embodiment of the present invention, the second given time period is less than the first given time period.

In an embodiment of the present invention, the latest resting state of charge is the first resting state of charge.

In an embodiment of the present invention, the latest second charging voltage EST_V2=BV2+ΔV×Table.A[Snew]/ΔA, BV2 represents the latest second present resting open-circuit voltage, ΔV represents the voltage difference, ΔA represents the findable charging current, Snew represents the latest resting state of charge, Table.A[Snew] represents the charging current corresponding to the latest resting state of charge as the remaining state of charge of the second curve, and ΔV, ΔA, and Table.A[Snew] are absolute values.

In an embodiment of the present invention, the first charging voltage EST_V1=BV1+ΔV×Table.A[Snow]/ΔA, BV1 represents the first present resting open-circuit voltage, ΔV represents the voltage difference, ΔA represents the findable charging current, Snow represents the present state of charge, Table.A[Snow] represents the charging current corresponding to the present state of charge as the remaining state of charge of the second curve, and ΔV, ΔA, and Table.A[Snow] are absolute values.

To sum up, the method for estimating a state of charge uses the Coulomb integration method to calculate the state of charge of the battery in the charging process to generate the first curve and the second curve and update the battery capacity, thereby avoiding the loss of battery capacity and errors in state of charge due to battery aging and using the first curve and the second curve to implement the open-circuit voltage look-up table method without resting the battery for a long time.

### BRIEF DESCRIPTION OF THE DRAWINGS

FIG. 1 is a diagram schematically illustrating a device for estimating a state of charge according to an embodiment of the present invention;

FIG. 2(a) and FIG. 2(b) are flowcharts of a method for estimating a state of charge according to an embodiment of the present invention;

FIG. 3 is a diagram schematically illustrating a first curve according to an embodiment of the present invention;

FIG. 4 is a diagram schematically illustrating a second curve according to an embodiment of the present invention;

FIG. 5 is a diagram schematically illustrating the waveforms of a charging voltage and a charging current in a charging process according to an embodiment of the present invention;

FIG. 6 is a flowchart of a constant current mode according to an embodiment of the present invention;

FIG. 7 is a flowchart of a first process for estimating a state of charge according to an embodiment of the present invention;

FIG. 8 is a flowchart of a second process for estimating a state of charge according to an embodiment of the present invention.

### DETAILED DESCRIPTION OF THE INVENTION

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express that the embodiment in the invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Certain terms are used throughout the description and the claims to refer to particular components. One skilled in the art appreciates that a component may be referred to as different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to compass any indirect or direct connection. Accordingly, if this disclosure mentioned that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the article “a” and “the” includes the meaning of “one or at least one” of the element or component. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. Every example in the present specification cannot limit the claimed scope of the invention.

In the following description, a method for estimating a state of charge will be provided. The method for estimating a state of charge uses the Coulomb integration method to calculate the state of charge of a battery in a charging process to generate the first curve and the second curve and update the battery capacity, thereby avoiding the loss of battery capacity and errors in state of charge due to battery aging and using a first curve and a second curve to implement the open-circuit voltage look-up table method without resting the battery for a long time.

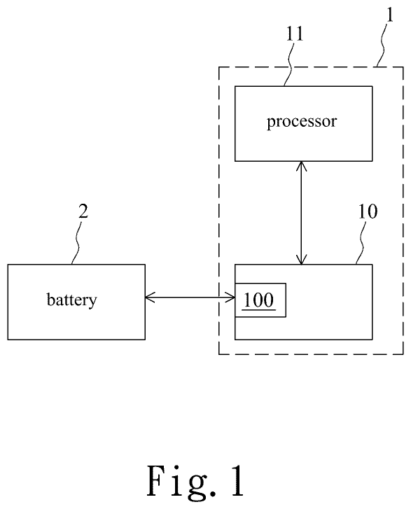

FIG. 1 is a diagram schematically illustrating a device for estimating a state of charge according to an embodiment of the present invention. Referring to FIG. 1, a device 1 for estimating a state of charge includes a charger 10 and a processor 11. The charger 10 has an electric signal detector 100 that can detect the voltage of the battery 2 and a charging voltage and a charging current provided by the charger 10 for the battery 2. The charger 10 is coupled between the processor 11 and the battery 2.

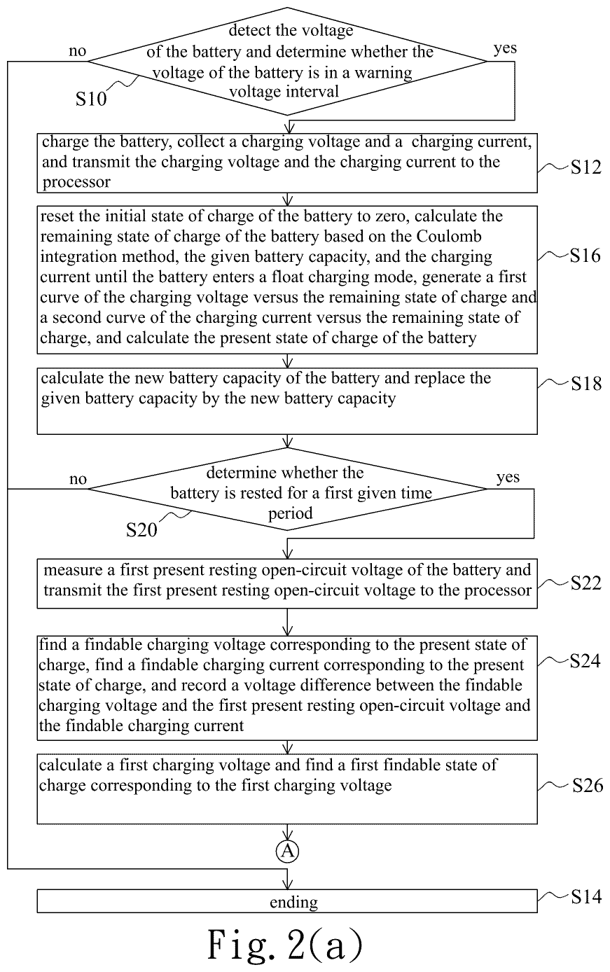

FIG. 2(a) and FIG. 2(b) are flowcharts of a method for estimating a state of charge according to an embodiment of the present invention. Please refer to FIG. 1 and FIG. 2(a). Firstly, in Step S10, the charger 10 uses the electric signal detector 100 to detect the voltage of the battery 2 and determine whether the voltage of the battery 2 is in a warning voltage interval. For example, the warning voltage interval is located between a first warning voltage and a second warning voltage. The second warning voltage may be equal to the first warning voltage multiplied by 1.02. When the voltage of the battery 2 is in the warning voltage interval, Step S12 is performed. In Step S12, the charger 10 charges the battery 2, collects a charging voltage and a charging current for charging the battery 2 in a charging process, and transmits the charging voltage and the charging current to the processor 11. When the voltage of the battery 2 is not in the warning voltage interval, Step S14 is performed. In Step S14, the whole process is ended.

In Step S16, the processor 11 resets the initial state of charge of the battery 2 to zero. The processor 11 calculates the remaining state of charge of the battery 2 in the charging process based on the Coulomb integration method, the given battery capacity of the battery 2, and the charging current until the battery 2 enters a float charging mode. The processor 11 generates a first curve of the charging voltage versus the remaining state of charge and a second curve of the charging current versus the remaining state of charge based on the remaining state of charge and the charging voltage and the charging current corresponding thereto. The processor 11 calculates the present state of charge of the battery 2 with the Coulomb integration method. The remaining state of charge of the battery 2 is represented with formula (1).

$$SOC ( t ) = SOC ( {t}_{0} ) + \frac{{\int }_{t}^{{t}_{0}} Idt}{C N} \qquad ( 1 )$$

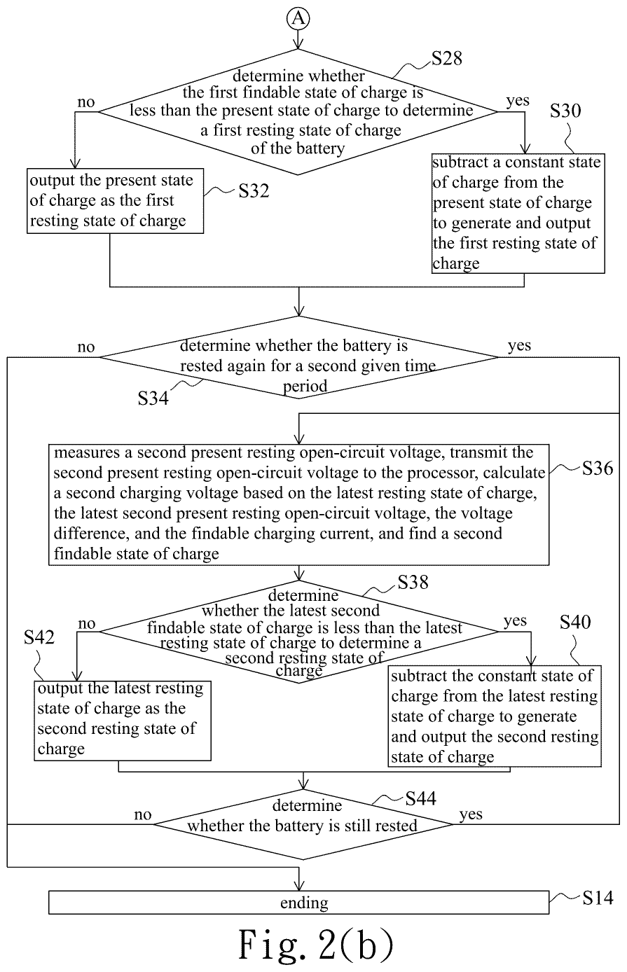

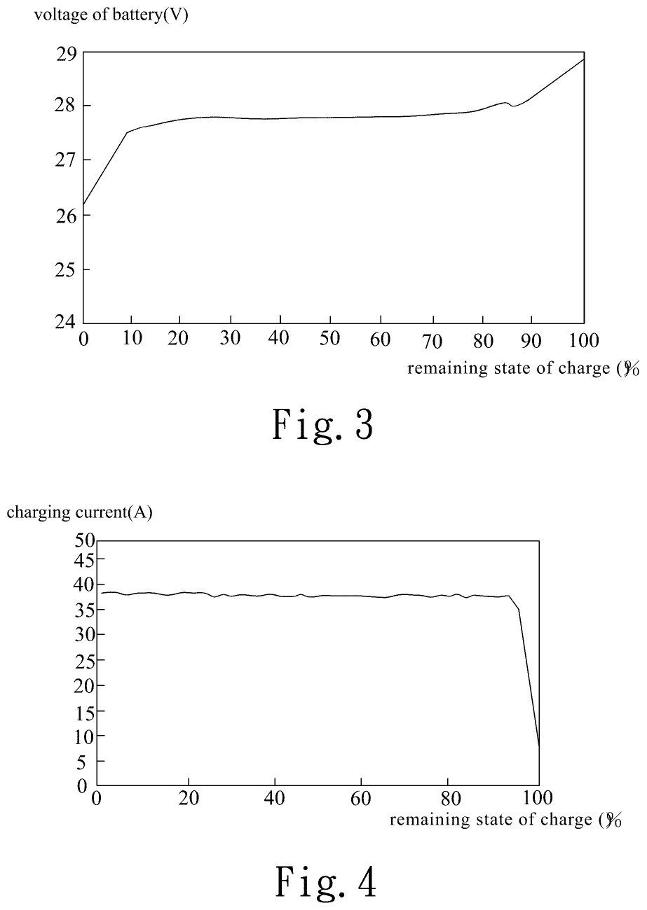

SOC(t) represents the remaining state of charge of the battery 2 at time point t. When the battery 2 enters the float charging mode, SOC(t) represents the present state of charge of the battery 2. SOC(t₀) represents the initial state of charge of the battery 2 at time point t₀. I represents the charging current. CN represents the given battery capacity of the battery 2. FIG. 3 is a diagram schematically illustrating a first curve according to an embodiment of the present invention. FIG. 4 is a diagram schematically illustrating a second curve according to an embodiment of the present invention. The first curve and the second curve are respectively shown in FIG. 3 and FIG. 4. FIG. 3 and FIG. 4 record the results caused by rapidly testing the battery 2 in the charging process. In FIG. 3, the charging voltage is equal to the voltage of the battery 2.

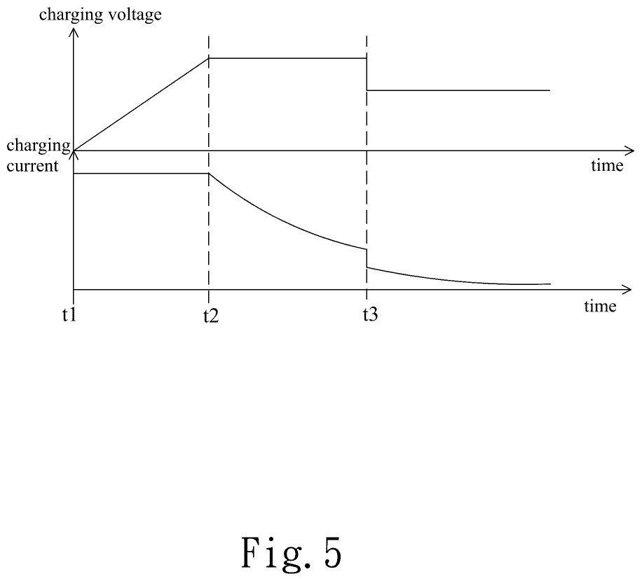

FIG. 5 is a diagram schematically illustrating the waveforms of a charging voltage and a charging current in a charging process according to an embodiment of the present invention. Referring to FIG. 1 and FIG. 5, the charging process of the battery 2 includes a constant current mode between time points t1 and t2, a constant voltage mode between time points t2 and t3, and a float charging mode after time point t3. The constant current mode, the constant voltage mode, and the float charging mode sequentially occur. In the constant current mode, the charging current is a constant current and the charging voltage is a rising voltage. In the constant voltage mode, the charging current is a descending current and the charging voltage is a constant voltage. The charging current in the float charging mode is less than the charging currents in the constant voltage mode and the constant current mode. For example, the charging current in the float charging mode may be less than one-tenth of the charging current in the constant current mode. Before the battery 2 enters the float charging mode, the processor 11 calculates the remaining state of charge of the battery 2 in the charging process based on the Coulomb integration method, the given battery capacity, and the charging current in the constant current mode and the constant voltage mode.

Please refer to FIG. 1 and FIG. 2(a). In Step S18, an update step is performed. In the update step, the processor 11 calculates the new battery capacity of the battery 2 based on the start time point of the charging process, the time point corresponding to the float charging mode, and the charging current and replaces the given battery capacity by the new battery capacity, thereby avoiding the loss of battery capacity and errors in the state of charge caused by battery aging. In Step S20, the processor 11 determines whether the battery 2 is rested for a first given time period. Specifically, when the processor 11 determines that the charging current is zero, the battery 2 is rested. When the battery 2 is rested for the first given time period, Step S22 is performed. When the battery 2 is not rested for the first given time period, Step S14 is performed. In Step S22, the chargers 10 uses the electric signal detector 100 to measure a first present resting open-circuit voltage of the battery 2 after resting the battery 2 and transmits the first present resting open-circuit voltage to the processor 11. In Step S24, the processor 11 finds from the first curve a findable charging voltage corresponding to the present state of charge, finds from the second curve a findable charging current corresponding to the present state of charge, and records a voltage difference between the findable charging voltage and the first present resting open-circuit voltage and the findable charging current. In Step S26, the processor 11 calculates a first charging voltage based on the present state of charge, the first present resting open-circuit voltage, the voltage difference, and the findable charging current and finds from the first curve a first findable state of charge corresponding to the first charging voltage. In some embodiments of the present invention, the first charging voltage EST_V1=BV1+ΔV×Table.A[Snow]/ΔA, BV1 represents the first present resting open-circuit voltage, ΔV represents the voltage difference, ΔA represents the findable charging current, Snow represents the present state of charge, Table.A[Snow] represents the charging current corresponding to the present state of charge as the remaining state of charge of the second curve, and ΔV, ΔA, and Table.A[Snow] are absolute values. Please refer to FIG. 1 and FIG. 2(b). After Step S26, Step S28 is performed. In Step S28, the processor 11 determines whether the first findable state of charge is less than the present state of charge to determine a first resting state of charge of the battery 2. When the first findable state of charge is less than the present state of charge, Step S30 is performed. In Step S30, the processor 11 subtracts a constant state of charge from the present state of charge to generate and output the first resting state of charge. The constant state of charge is greater than 0% and the constant state of charge is less than or equal to 1%. When the first findable state of charge is not less than the present state of charge, Step S32 is performed. In Step S32, the processor 11 outputs the present state of charge as the first resting state of charge. In some embodiments of the present invention, Steps S10, S18, or both can be omitted. When Step S18 is omitted, Step S20 is directly performed after Step S16 is performed.

In some embodiments of the present invention, the following steps are performed after the processor 11 determines the first resting state of charge. In Step S34, the processor 11 determines whether the battery 2 is rested again for a second given time period. The second given time period is less than the first given time period. For example, the first given time period is 30 minutes and the second given time period is 10 minutes. When the battery 2 is not rested again for the second given time period, Step S14 is performed. When the battery 2 is rested again for the second given time period, Step S36 is performed. In Step S36, the charger 10 uses the electric signal detector 100 to measures a second present resting open-circuit voltage of the battery 2 and transmits the second present resting open-circuit voltage to the processor 11. The processor 11 calculates a second charging voltage based on the latest resting state of charge, the latest second present resting open-circuit voltage, the voltage difference, and the findable charging current. The processor 11 finds a second findable state of charge corresponding to the latest second charging voltage from the first curve. The latest second charging voltage EST_V2=BV2+ΔV×Table.A[Snew]/ΔA, BV2 represents the latest second present resting open-circuit voltage, ΔV represents the voltage difference, ΔA represents the findable charging current, Snew represents the latest resting state of charge, Table.A[Snew] represents the charging current corresponding to the latest resting state of charge as the remaining state of charge of the second curve, and ΔV, ΔA, and Table.A[Snew] are absolute values. In Step S38, the processor 11 determines whether the latest second findable state of charge is less than the latest resting state of charge to determine a second resting state of charge of the battery 2. When the latest second findable state of charge is less than the latest resting state of charge, Step S40 is performed. In Step S40, the processor 11 subtracts the constant state of charge from the latest resting state of charge to generate and output the second resting state of charge. When the latest second findable state of charge is not less than the latest resting state of charge, Step S42 is performed. In Step S42, the processor 11 outputs the latest resting state of charge as the second resting state of charge. When Step S38 is performed for the first time, the latest resting state of charge is the first resting state of charge. After Steps S40 and S42, Step S44 is performed. In Step S44, the processor 11 determines whether the battery 2 is still rested. If the result is yes, the process returns to Step S36. If the result is no, the process proceeds to Step S14. Provided that substantially the same result is achieved, the steps of the flowchart shown in FIG. 2(a) need not be in the exact order shown and need not be contiguous, that is, other steps can be intermediate.

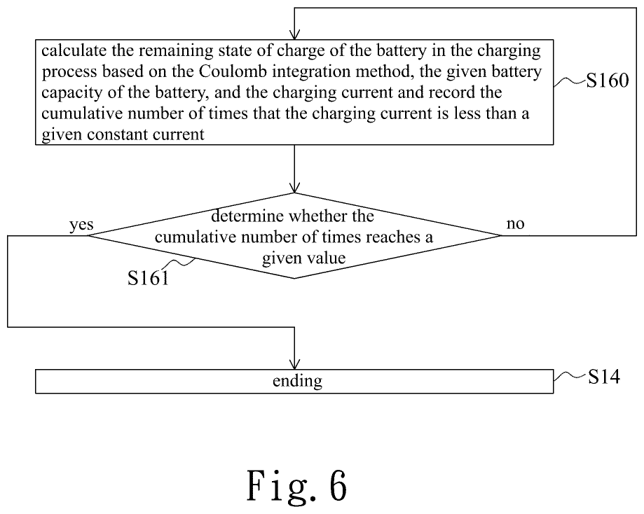

FIG. 6 is a flowchart of a constant current mode according to an embodiment of the present invention. Referring to FIG. 1 and FIG. 6, the constant current mode may include Steps S160 and S161. In Step S160, the processor 11 calculates the remaining state of charge of the battery 2 in the charging process based on the Coulomb integration method, the given battery capacity of the battery 2, and the charging current and records the cumulative number of times that the charging current is less than a given constant current. For example, the given constant current can be 20% of the maximum charging current in the constant current mode, but the present invention is not limited thereto. In Step S161, the processor 11 determines whether the cumulative number of times reaches a given value. For example, the cumulative number of times is 60. When the cumulative number of times reaches the given value, Step S14 is performed. When the cumulative number of times does not reach the given value, the process returns to Step S160.

The processor 11 endlessly receives the charging voltage and the charging current. When the charging current is equal to zero, the processor 11 determines that the battery 2 is rested. When the charging current is greater than zero, the processor 11 determines that the battery 2 is charged. After Step 14 in FIG. 2(b), the processor 11 determines that the battery 2 is charged or rested. When the battery 2 is charged, at least one first process for estimating a state of charge. When the battery 2 is rested, at least one second process for estimating a state of charge.

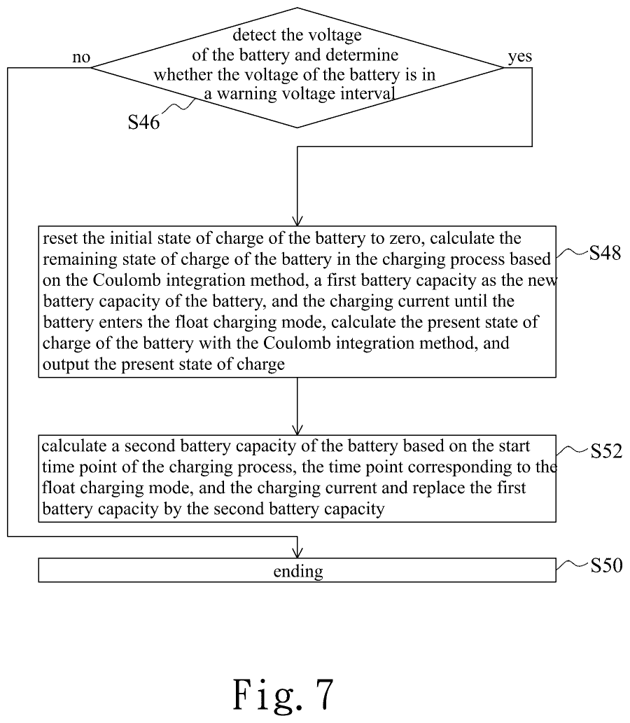

FIG. 7 is a flowchart of a first process for estimating a state of charge according to an embodiment of the present invention. Referring to FIG. 1 and FIG. 7, the first process for estimating a state of charge is introduced as follows. In Step S46, the charger 10 uses the electric signal detector 100 to detect the voltage of the battery 2 and determines whether the voltage of the battery 2 is in a warning voltage interval. When the voltage of the battery 2 is in the warning voltage interval, Step S48 is performed. In Step S48, the processor 11 resets the initial state of charge of the battery 2 to zero. The processor 11 calculates the remaining state of charge of the battery 2 in the charging process based on the Coulomb integration method, a first battery capacity as the new battery capacity of the battery 2, and the charging current until the battery 2 enters the float charging mode. The processor 11 calculates the present state of charge of the battery 2 with the Coulomb integration method and outputs the present state of charge. The remaining state of charge of the battery 2 is represented with formula (2).

$$SOC ( t ) = SOC ( {t}_{0}^{′} ) + \frac{{\int }_{t}^{{t}_{{0}^{′}}} Idt}{CN ′} \qquad ( 2 )$$

SOC(t) represents the remaining state of charge of the battery 2 at time point t. When the battery 2 enters the float charging mode, SOC(t) represents the present state of charge of the battery 2.

$$SOC ( {t}_{0}^{′} )$$

represents the initial state of charge of the battery 2 at time point t₀. I represents the charging current. CN′ represents the first battery capacity of the battery 2. When the voltage of the battery 2 is not in the warning voltage interval, Step S50 is performed. In Step S50, the first process for estimating the state of charge is ended. After Step S48, Step S52 is performed. In Step S52, the processor 11 calculates a second battery capacity of the battery 2 based on the start time point of the charging process, the time point corresponding to the float charging mode, and the charging current and replaces the first battery capacity by the second battery capacity, thereby avoiding the loss of battery capacity and errors in the state of charge caused by battery aging.

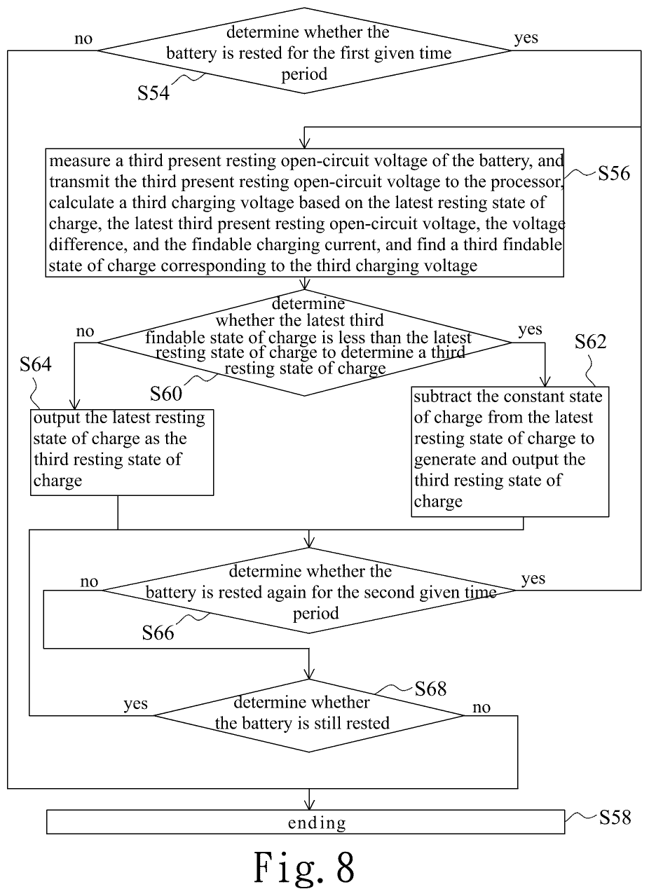

FIG. 8 is a flowchart of a second process for estimating a state of charge according to an embodiment of the present invention. Referring to FIG. 1 and FIG. 8, the second process for estimating a state of charge is introduced as follows. In Step S54, the processor 11 determines whether the battery 2 is rested for the first given time period. When the battery 2 is rested for the first given time period, Step S56. When the battery 2 is not rested for the first given time period, Step S58. In Step S56, the charger 10 uses the electric signal detector 100 to measure a third present resting open-circuit voltage of the battery 2 and transmits the third present resting open-circuit voltage to the processor 11. The processor 11 calculates a third charging voltage based on the latest resting state of charge, the latest third present resting open-circuit voltage, the voltage difference, and the findable charging current and finds from the first curve a third findable state of charge corresponding to the third charging voltage. In some embodiments of the present invention, the third charging voltage EST_V3=BV3+ΔV×Table.A[Snew]/ΔA, BV3 represents the third present resting open-circuit voltage, ΔV represents the voltage difference, ΔA represents the findable charging current, Snew represents the latest resting state of charge, and Table.A[Snew] represents the charging current corresponding to the latest resting state of charge as the remaining state of charge of the second curve. In Step S58, the second process for estimating the state of charge is ended. After Step S56, Step S60 is performed. In Step S60, the processor 11 determines whether the latest third findable state of charge is less than the latest resting state of charge to determine a third resting state of charge of the battery 2. When the latest third findable state of charge is less than the latest resting state of charge, Step S62 is performed. In Step S62, the processor 11 subtracts the constant state of charge from the latest resting state of charge to generate and output the third resting state of charge. When the latest third findable state of charge is not less than the latest resting state of charge, Step S64 is performed. In Step S64, the processor 11 outputs the latest resting state of charge as the third resting state of charge. When the first process for estimating the state of charge is performed for the first time, the latest resting state of charge is the latest second resting state of charge. After Steps S62 or S64, Step S66 is performed. In Step S66, the processor 11 determines whether the battery 2 is rested again for the second given time period. When the battery 2 is not rested again for the second given time period, Step S68 is performed. When the battery 2 is rested again for the second given time period, the process returns to Step S56. In Step S68, the processor 11 determines whether the battery 2 is still rested. If the result is yes, the process returns to Step S66. If the result is no, the process proceeds to Step S58. Provided that substantially the same result is achieved, the steps of the flowchart shown in FIG. 8 need not be in the exact order shown and need not be contiguous, that is, other steps can be intermediate.

According to the embodiments provided above, the method for estimating a state of charge uses the Coulomb integration method to calculate the state of charge of the battery in the charging process to generate the first curve and the second curve and update the battery capacity, thereby avoiding the loss of battery capacity and errors in state of charge due to battery aging and using the first curve and the second curve to implement the open-circuit voltage look-up table method without resting the battery for a long time.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A method for estimating a state of charge, comprising:
charging a battery and collecting a charging voltage and a charging current for charging the battery in a charging process;
resetting an initial state of charge of the battery to zero, calculating a remaining state of charge of the battery in the charging process based on a Coulomb integration method, a given battery capacity of the battery, and the charging current until the battery enters a float charging mode, generating a first curve of the charging voltage versus the remaining state of charge and a second curve of the charging current versus the remaining state of charge based on the remaining state of charge and the charging voltage and the charging current corresponding thereto, and calculating a present state of charge of the battery with the Coulomb integration method;
measuring a first present resting open-circuit voltage of the battery after resting the battery;
finding from the first curve a findable charging voltage corresponding to the present state of charge, finding from the second curve a findable charging current corresponding to the present state of charge, and recording a voltage difference between the findable charging voltage and the first present resting open-circuit voltage and the findable charging current;
calculating a first charging voltage based on the present state of charge, the first present resting open-circuit voltage, the voltage difference, and the findable charging current and finding from the first curve a first findable state of charge corresponding to the first charging voltage; and
determining whether the first findable state of charge is less than the present state of charge to determine a first resting state of charge of the battery:
when the first findable state of charge is less than the present state of charge, subtracting a constant state of charge from the present state of charge to generate and output the first resting state of charge, wherein the constant state of charge is greater than 0% and the constant state of charge is less than or equal to 1%; and
when the first findable state of charge is not less than the present state of charge, outputting the present state of charge as the first resting state of charge.

2. The method for estimating a state of charge according to claim 1, further comprising an update step, and in the update step, a new battery capacity of the battery is calculated based on a start time point of the charging process, a time point corresponding to the float charging mode, and the charging current and the given battery capacity is replaced by the new battery capacity.

3. The method for estimating a state of charge according to claim 1, further comprising following steps before the step of charging the battery:
determining whether a voltage of the battery is in a warning voltage interval:
when the voltage of the battery is in the warning voltage interval, charging the battery; and
when the voltage of the battery is not in the warning voltage interval, ending.

4. The method for estimating a state of charge according to claim 1, wherein before the battery enters the float charging mode, the remaining state of charge of the battery in the charging process is calculated based on the Coulomb integration method, the given battery capacity of the battery, and the charging current in a constant current mode and a constant voltage mode.

5. The method for estimating a state of charge according to claim 4, wherein the constant current mode comprises:
calculating the remaining state of charge of the battery in the charging process based on the Coulomb integration method, the given battery capacity of the battery, and the charging current and recording cumulative number of times that the charging current is less than a given constant current; and
determining whether the cumulative number of times reaches a given value:
when the cumulative number of times reaches the given value, ending; and
when the cumulative number of times does not reach the given value, returning to the step of calculating the remaining state of charge of the battery in the charging process based on the Coulomb integration method, the given battery capacity of the battery, and the charging current and recording the cumulative number of times.

6. The method for estimating a state of charge according to claim 1, wherein in the step of resting the battery, the battery is rested for a first given time period.

7. The method for estimating a state of charge according to claim 6, further comprising following steps after determining the first resting state of charge:
determining whether the battery is rested again for a second given time period:
when the battery is not rested again for the second given time period, ending; and
when the battery is rested again for the second given time period, performing following steps:
measuring a second present resting open-circuit voltage of the battery, calculating a second charging voltage based on the latest resting state of charge, the latest second present resting open-circuit voltage, the voltage difference, and the findable charging current, and finding a second findable state of charge corresponding to the latest second charging voltage from the first curve; and
determining whether the latest second findable state of charge is less than the latest resting state of charge to determine a second resting state of charge of the battery:
when the latest second findable state of charge is less than the latest resting state of charge, subtracting the constant state of charge from the latest resting state of charge to generate and output the second resting state of charge; and
when the latest second findable state of charge is not less than the latest resting state of charge, outputting the latest resting state of charge as the second resting state of charge.

8. The method for estimating a state of charge according to claim 7, wherein the second given time period is less than the first given time period.

9. The method for estimating a state of charge according to claim 7, wherein the latest resting state of charge is the first resting state of charge.

10. The method for estimating a state of charge according to claim 7, wherein the latest second charging voltage EST_V2=BV2+ΔV×Table.A[Snew]/ΔA, BV2 represents the latest second present resting open-circuit voltage, ΔV represents the voltage difference, ΔA represents the findable charging current, Snew represents the latest resting state of charge, Table.A[Snew] represents the charging current corresponding to the latest resting state of charge as the remaining state of charge of the second curve, and ΔV, ΔA, and Table.A[Snew] are absolute values.

11. The method for estimating a state of charge according to claim 1, wherein the first charging voltage EST_V1=BV1+ΔV×Table.A[Snow]/ΔA, BV1 represents the first present resting open-circuit voltage, ΔV represents the voltage difference, ΔA represents the findable charging current, Snow represents the present state of charge, Table.A[Snow] represents the charging current corresponding to the present state of charge as the remaining state of charge of the second curve, and ΔV, ΔA, and Table.A[Snow] are absolute values.
